(19) United States
(12) Patent Application Publication
(10) Pub. No.: US 2012/0002707 A1
(43) Pub. Date: Jan. 5, 2012

(54) PLL FREQUENCY SYNTHESIZER

(75) Inventor: Hidetoshi YAMASAKI, Hyogo (JP)

(73) Assignee: PANASONIC CORPORATION, Osaka (JP)

(21) Appl. No.: 13/233,806

(22) Filed: Sep. 15, 2011

Related U.S. Application Data
(63) Continuation of application No. PCT/JP2010/004839, filed on Jul. 30, 2010.

(30) Foreign Application Priority Data
Mar. 15, 2010 (JP) 2010-058194

(51) Int. Cl. H03D 3/24; H04B 1/38; H03L 7/06

(52) U.S. Cl. 375/219; 327/156

(57) ABSTRACT

A PLL frequency synthesizer includes: a phase comparator configured to detect a phase difference between a reference clock signal and an output signal of the PLL frequency synthesizer; a loop filter configured to output a control value composed of a total of an integer value and a decimal value; a first controller configured to output a first control signal corresponding to the integer value in synchronization with a first clock; a second controller configured to output a second control signal representing the decimal value as a mean value in synchronization with a second clock, and when the PLL frequency synthesizer is in a locked state, to limit a range of values which the second control signal can have to a range in the locked state; and a digital controlled oscillator configured to oscillate at a frequency based on a combination of frequency control by the first and second control signals.

### CROSS-REFERENCE TO RELATED APPLICATION

This is a continuation of PCT International Application PCT/JP2010/004839 filed on Jul. 30, 2010, which claims priority to Japanese Patent Application No. 2010-058194 filed on Mar. 15, 2010. The disclosures of these applications including the specifications, the drawings, and the claims are hereby incorporated by reference in their entirety.

### BACKGROUND

The present disclosure relates to PLL frequency synthesizers used in, for example, wireless communication devices, and wireless measurement devices.

Conventionally, there have been all-digital phase-locked loop (ADPLL) frequency synthesizers which include digitally-controlled oscillators (DCOs) and use dithering by ΔΣ modulators to improve frequency resolution. Such an ADPLL frequency synthesizer is disclosed in, for example, U.S. Patent Application Publication No. 2002/0159555. FIG. 17 is a view illustrating a configuration of a conventional ADPLL frequency synthesizer 105 disclosed in U.S. Patent Application Publication No. 2002/0159555.

In FIG. 17, a digital controlled oscillator (DCO) 110 includes a varactor array 111, a varactor array 112, an inductor element 113, and a negative resistive element 114. The varactor array 111 and the varactor array 112 each include a plurality of varactors. All the varactors have the same capacity. The capacitance value of each varactor is controlled by a binary control signal. When the capacitance value of the varactor is controlled, the oscillation frequency f_{CKV} of the DCO 110 is controlled.

The oscillation frequency f_{CKV} is indicated by Expression (1) by using a total capacitance value C of the varactor array 111 and the varactor array 112, and an inductance value L of the inductor element 113.

$${f}_{cxr} = \frac{1}{2 π \sqrt{LC}} \qquad [ Expression 1 ]$$

Specifically, the capacitance value of the varactor is controlled as follows. First, a phase comparator 82 compares the phase of a reference signal F_{REF} with the phase of an output CKV of the DCO 110, thereby generating a phase error signal. Then, a loop filter 84 filters the phase error signal, and outputs the filtered phase error signal as a DCO control signal TUNE_T. The TUNE_T signal includes an integer part and a decimal part. The integer part is input to a tracking varactor controlling section 86, and the decimal part is input to a tracking varactor controlling section 87.

The tracking varactor controlling section 86 converts the integer part to an oscillator tuning word (OTW) Integer signal, and outputs the OTW Integer signal to the varactor array 111, thereby adjusting the capacity of the varactor array 111. On the other hand, the tracking varactor controlling section 87 converts the decimal part to an OTW Fract signal, and outputs the OTW Fract signal to the varactor array 112, thereby adjusting the capacity of the varactor array 112. The tracking varactor controlling section 87 includes a ΔΣ modulator.

As described above, in the conventional ADPLL frequency synthesizer, a negative feedback system is established, and phase locked loop (PLL) operation is performed.

Here, the tracking varactor controlling section 86 operates in synchronization with a CKR clock which is a signal obtained by retiming the reference signal F_{REF} by the CKV. The tracking varactor controlling section 87 operates in synchronization with a CKVD clock which is a signal obtained by dividing the CKV by a frequency divider 85. The frequency of the CKVD is set to be sufficiently higher than the frequency of the CKR. This produces a dithering effect by the ΔΣ modulator of the tracking varactor controlling section 87, and improves the frequency resolution of the CKV signal.

### SUMMARY

However, in the conventional ADPLL frequency synthesizer 105 described above, the clock signal CKR is asynchronous with the clock signal CKVD, so that timing of a change of the OTW Integer signal does not usually match timing of a change of the OTW Fract signal. Thus, even when the value of the DCO control signal TUNE_T approaches a target value corresponding to a target oscillation frequency, a phenomenon in which an error between an OTW(Total) target value and an OTW(Total) temporarily becomes large occurs if the OTW(Total) target value is close to an integer value, where the OTW(Total) target value is a total of an OTW Integer and an OTW Fract which are determined correspondingly to a target value of the TUNE_T, and the OTW(Total) is a total of an actual OTW Integer and an actual OTW Fract. When this phenomenon repeatedly occurs, phase noise characteristics of the ADPLL frequency synthesizer may degrade.

Note that to simplify the description, the OTW(Total) target value which is the total of the OTW Integer and the OTW Fract which are determined correspondingly to the target value of the DCO control signal TUNE_T is hereinafter simply referred to as a target value of the TUNE_T.

With reference to FIG. 18, the problem discussed above will be described in detail. For example, it is provided that the target value of the TUNE_T (target OTW) is 122.09 which is close to an integer value 122. Note that an output (i.e., OTW Fract) of the ΔΣ modulator of the tracking varactor controlling section 87 is any one of values 0, 1, 2, and 3 output in synchronization with the clock CKVD, and varies so that its mean value over a long period of time is close to a value obtained by adding a decimal value of the target value of the TUNE_T to a particular integer (0 or 1 or 2). In this case, there may be two cases where the values of the OTW Integer and the OTW Fract correspond to the target value of the TUNE_T, that is, the case where the OTW Integer is 120 and the OTW Fract is 2.09, and the case where the OTW Integer is 121 and the OTW Fract is 1.09. Now, at a certain rising time of the CKR (e.g., at about 1.7768 msec in FIG. 18), the value of the TUNE_T is 121.99 which is slightly less than the integer value 122, where correspondingly to 121 of an integer part TUNE_T Integer, 120 is assigned to the value of the OTW Integer, and correspondingly to 0.99 of a decimal part TUNE_T Fract, 1.99 is assigned to the value of the OTW Fract. Here, the output of the ΔΣ modulator varies mostly to have a value of 1, 2, or 3 so that the mean value of the decimal part is about 1.99. Thus, at this point, the error between the target value, 122.09, of the TUNE_T and a mean value of the OTW(Total) which is the total of the OTW Integer and the OTW Fract (hereinafter simply referred to as error) is substantially 0.

However, when the value of the TUNE_T slightly changes from this state to 122.01 which is greater than 122 (e.g., at about 1.777 msec in FIG. 18), 121 is assigned, correspondingly to the value of the integer part the TUNE_T, to the value of the OTW Integer, and 1.01 is assigned, correspondingly to the value of the decimal part of the TUNE_T, to the value of the OTW Fract, so that “carry” occurs. Here, “carry” means that the value of the integer part of the TUNE_T increases by 1. Moreover, “borrow” means that the value of the integer part of the TUNE_T decreases by 1.

In synchronization with the CKVD immediately after the carry, the output of the ΔΣ modulator changes from a state in which the output varies mostly to have a value of 1, 2, or 3 to a state in which the output varies mostly to have a value of 0, 1, or 2 so that a mean value of the OTW Fract is 1.01. On the other hand, the frequency of the clock signal which changes the value of the OTW Integer is generally lower than that of the CKVD, so that the value of the OTW Integer changes from 120 to 121 behind timing of a change of variation of the OTW Fract.

Therefore, for a certain period after the variation state of the value of the OTW Fract has changed, the value of the OTW Integer is continuously in a state in which the value of the OTW Integer is offset by 1 from 121 which is an integer value corresponding to the TUNE_T. As a result, the error between the target value of the TUNE_T and the OTW(Total) temporarily becomes large (over a period indicated by an arrow in FIG. 18).

Such a phenomenon in which the error between the target value of the TUNE_T and the OTW(Total) temporarily becomes large can occur also when “borrow” occurs. For example, a state in which the target value of the TUNE_T is likewise 122.09 which is close to an integer value, and the value of the TUNE_T at a certain rising time of the CKR is 122.02 is considered. In this state, it is provided that correspondingly to the value of the TUNE_T, for example, 121 is assigned to the value of the OTW Integer, and 1.02 is assigned to the value of the OTW Fract. When a ΔΣ modulator configured to output a value of 0, 1, 2, or 3 is used, the output of the ΔΣ modulator varies mostly to have a value of 0, 1, or 2 so that the mean value of the OTW Fract is 1.02. In this way, the error between the target value of the TUNE_T and the mean value of the OTW(Total) which is the total of the OTW Integer and the OTW Fract is substantially 0.

However, when the value of the TUNE_T slightly changes from this state to, for example, 121.99, “borrow” occurs.

In synchronization with the CKVD immediately after the borrow, the output of the ΔΣ modulator (i.e., OTW Fract) changes from a state in which the output varies mostly to have a value of 0, 1, or 2 to a state in which the output varies mostly to have a value of 1, 2, or 3 so that the mean value the OTW Fract is 1.99. On the other hand, due to the difference in frequency of the clock signals, the value of the OTW Integer changes from 121 to 120 behind timing of the change of the OTW Fract.

Therefore, for a certain period after the variation state of the value of the OTW Fract has changed, the value of the OTW Integer is continuously in a state in which the value of the OTW Integer is offset by 1 from 120 which is an integer value corresponding to the TUNE_T. As a result, the error temporarily becomes large.

As described above, when the target value of the TUNE_T is close to an integer value, “carry” or “borrow” occurs, and the phenomenon in which the error between the target value of the TUNE_T and the OTW(Total) which is the total of the OTW Integer and the OTW Fract temporarily becomes large is likely to occur. If such a phenomenon occurs, the phase noise characteristics of the ADPLL frequency synthesizer may degrade.

In view of the foregoing, an example PLL frequency synthesizer of the present disclosure can improve the phase noise characteristics.

An example PLL frequency synthesizer includes: a phase comparator configured to detect a phase difference between a reference clock signal and an output signal of the PLL frequency synthesizer; a loop filter configured to output a control value composed of a total of an integer value and a decimal value which are based on the phase difference; a first frequency controlling section configured to output a first digital control signal corresponding to the integer value in synchronization with a first clock signal; a second frequency controlling section configured to output a second digital control signal representing the decimal value as a mean value in synchronization with a second clock signal which is higher in frequency than the first clock signal, where when the PLL frequency synthesizer is in a locked state, the second frequency controlling section limits a range of values which the second digital control signal can have to a range in the locked state; and a digital controlled oscillator configured to oscillate at a frequency based on a combination of frequency control by the first digital control signal and frequency control by the second digital control signal.

With this configuration, even when the decimal value changes in the locked state of the PLL frequency synthesizer, the second digital control signal does not track the change of the decimal value, so that the decimal value represented by the second digital control signal is constant. Thus, the first digital control signal does not change due to changes of the range of values which the second digital control signal can have, which keeps a certain combination of frequency control by the first and second digital control signals in the locked state.

Another example PLL frequency synthesizer includes: a phase comparator configured to detect a phase difference between a reference clock signal and an output signal of the PLL frequency synthesizer; a loop filter configured to output a control value composed of a total of an integer value and a decimal value which are based on the phase difference; a first frequency controlling section configured to output a first digital control signal corresponding to the integer value in synchronization with a first clock signal, where when the PLL frequency synthesizer is in a locked state, the first frequency controlling section constantly outputs the first digital control signal in the locked state; a second frequency controlling section configured to output a second digital control signal representing the decimal value as a mean value in synchronization with a second clock signal which is higher in frequency than the first clock signal; and a digital controlled oscillator configured to oscillate at a frequency based on a combination of frequency control by the first digital control signal and frequency control by the second digital control signal.

With this configuration, even when the integer value changes in the locked state of the PLL frequency synthesizer, the first digital control signal is the same before and after the change of the integer value. Thus, the second digital control signal is in synchronization with a clock signal having a high frequency even when the second digital control signal tracks a change of the decimal value, so that through feedback control by the PLL frequency synthesizer, the second digital control signal immediately indicates the decimal value of a time point at which the synthesizer enters the locked state (lock point). This keeps a certain combination of frequency control by the first and second digital control signals in the locked state.

Still another example PLL frequency synthesizer includes: a phase comparator configured to detect a phase difference between a reference clock signal and an output signal of the PLL frequency synthesizer; a loop filter configured to output a control value composed of a total of an integer value and a decimal value which are based on the phase difference; a first frequency controlling section configured to output a first digital control signal corresponding to the integer value in synchronization with a first clock signal; a second frequency controlling section configured to output a second digital control signal representing the decimal value as a mean value in synchronization with a second clock signal which is higher in frequency than the first clock signal, where when the PLL frequency synthesizer is in a locked state, the second frequency controlling section compensates an amount of change of the integer value in a period after the integer value has changed before the first digital control signal changes; and a digital controlled oscillator configured to oscillate at a frequency based on a combination of frequency control by the first digital control signal and frequency control by the second digital control signal.

With this configuration, even when the integer value changes in the locked state of the PLL frequency synthesizer, the amount of the change is compensated, which keeps a certain combination of frequency control by the first and second digital control signals.

Yet another example PLL frequency synthesizer includes: a phase comparator configured to detect a phase difference between a reference clock signal and an output signal of the PLL frequency synthesizer; a loop filter configured to output a control value composed of a total of an integer value and a decimal value which are based on the phase difference; a first frequency controlling section configured to output a first digital control signal corresponding to the integer value in synchronization with a first clock signal; a second frequency controlling section configured to output a second digital control signal representing the decimal value as a mean value in synchronization with a second clock signal which is higher in frequency than the first clock signal; a clock generating section configured to retime the reference clock signal by the output of the PLL frequency synthesizer to obtain a retiming clock, and to further retime the retiming clock by the second clock signal to generate a clock signal as the first clock signal; and a digital controlled oscillator configured to oscillate at a frequency based on a combination of frequency control by the first digital control signal and frequency control by the second digital control signal.

With this configuration, the first digital control signal is output after several cycles of the second clock signal from timing of a change of the integer value. That is, time in which the first digital control signal tracks the change of the integer value decreases. Moreover, the second digital control signal is in synchronization with a clock signal having a high frequency, so that the second digital control signal immediately tracks the change of the decimal value. Thus, when the PLL frequency synthesizer is in a locked state, there is no difference between a control value to allow the digital controlled oscillator to oscillate at a preferable frequency and the total of the first and second digital control signals, so that frequency control by the digital controlled oscillator is stable.

### BRIEF DESCRIPTION OF THE DRAWINGS

FIG. 1 is a block diagram schematically illustrating an ADPLL frequency synthesizer of a first embodiment of the present invention.

FIG. 2 is a block diagram illustrating an example configuration of the OTF having a limiting function of FIG. 1.

FIG. 3 is a flowchart illustrating operation of the ADPLL frequency synthesizer of the first embodiment of the present invention.

FIG. 4 is a view illustrating a result of simulation of the operation of the ADPLL frequency synthesizer of the first embodiment of the present invention.

FIG. 5 is a block diagram schematically illustrating an ADPLL frequency synthesizer of a second embodiment of the present invention.

FIG. 6 is a block diagram illustrating an example configuration of the OTI having a latching function of FIG. 5.

FIG. 7 is a view illustrating a result of simulation of operation of the ADPLL frequency synthesizer of the second embodiment of the present invention.

FIG. 8 is a block diagram schematically illustrating a configuration of an ADPLL frequency synthesizer of a third embodiment of the present invention.

FIG. 9 is a block diagram illustrating an example configuration of the OTF having a compensating function of FIG. 8.

FIG. 10 is a view illustrating an example of changes of the DCO control signal and the capacity control signal of the third embodiment of the present invention.

FIG. 11 is a view illustrating a result of simulation of operation of the ADPLL frequency synthesizer of the third embodiment of the present invention.

FIG. 12 is a block diagram schematically illustrating a configuration of an ADPLL frequency synthesizer of a fourth embodiment of the present invention.

FIG. 13 is a block diagram illustrating an example configuration of the clock generating section of FIG. 12.

FIG. 14 is a view illustrating a result of simulation of operation of the ADPLL frequency synthesizer of the fourth embodiment of the present invention.

FIG. 15 is a view illustrating a configuration of a wireless communication device of an application example.

FIG. 16 is a view illustrating a television set in which the wireless communication device of the application example is installed.

FIG. 17 is a view illustrating a configuration of a conventional ADPLL frequency synthesizer.

FIG. 18 is a view illustrating an example of a change of the DCO control signal of the conventional ADPLL frequency synthesizer.

### DETAILED DESCRIPTION

Embodiments of the present invention will be described below in detail with reference to the drawings. Note that in the drawings, like reference characters are used to designate identical or equivalent elements, and explanation thereof is not repeated.

### First Embodiment

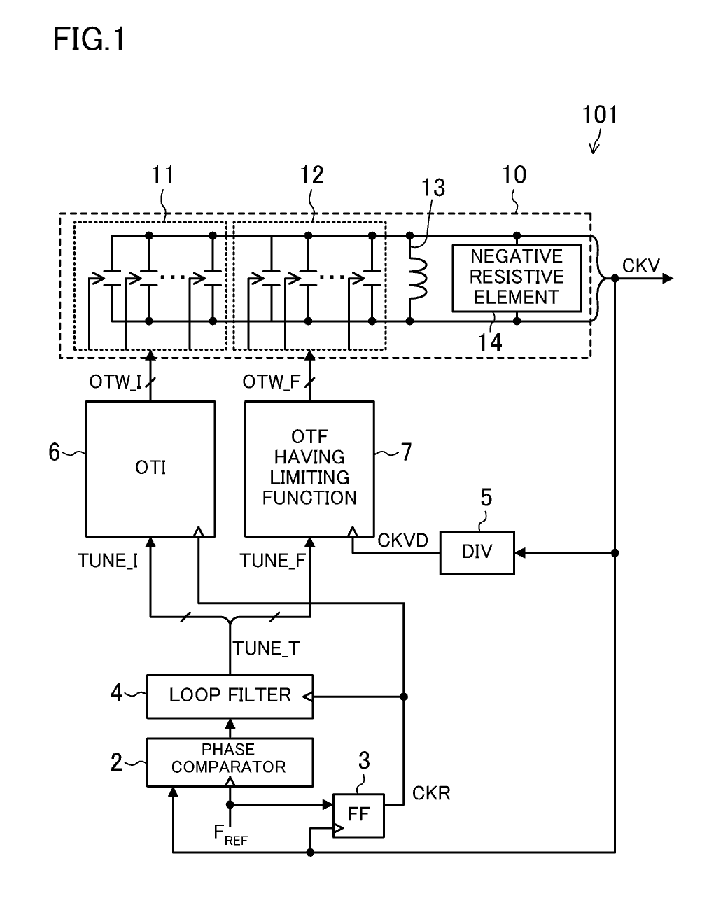

FIG. 1 is a block diagram schematically illustrating a configuration of an ADPLL frequency synthesizer of a first embodiment of the present invention. An ADPLL frequency synthesizer 101 includes a digital controlled oscillator (DCO) 10, a frequency divider 5, a flip flop 3, a phase comparator 2, a loop filter 4, an oscillator tuning integer (OTI 6), and an oscillator tuning fract (OTF 7). The OTI 6 and OTF 7 each serve as a tracking varactor controlling section.

The capacitance value of a varactor is controlled as follows. First, the phase comparator 2 compares the phase of a reference signal F_{REF} with the phase of an output CKV of the DCO 10 to generate a phase error signal. The loop filter 4 filters the phase error signal, and outputs the filtered phase error signal as a DCO control signal TUNE_T. The TUNE_T includes an integer part (hereinafter referred to as TUNE_I) and a decimal part (hereinafter referred to as TUNE_F). The TUNE_I is input to the OTI 6, and the TUNE_F is input to the OTF 7.

The OTI 6 converts the TUNE_I to an oscillator tuning word (OTW) Integer signal (hereinafter referred to as OTW_I), and outputs the OTW_I to a varactor array 11, thereby adjusting the capacity of the varactor array 11. On the other hand, the OTF 7 converts the TUNE_F to an OTW Fract signal (hereinafter referred to as OTW_F). The OTF 7 performs a later-described predetermined process on the input TUNE_F, and outputs the OTW_F to a varactor array 12, thereby adjusting the capacity of the varactor array 12.

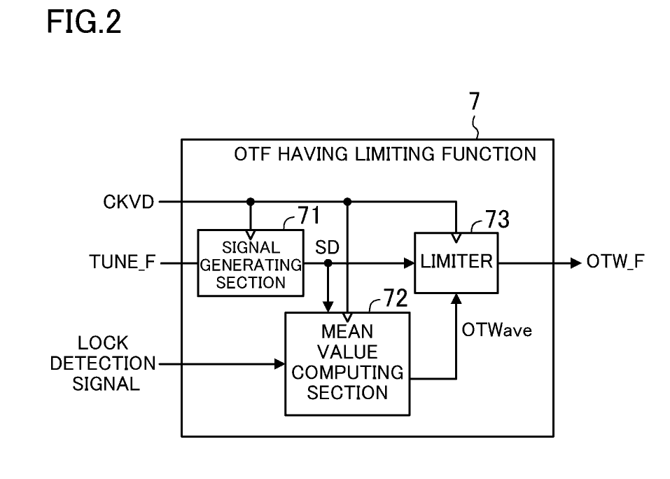

FIG. 2 is a block diagram illustrating an example configuration of the OTF 7 having a limiting function. In FIG. 2, the OTF 7 includes a signal generating section 71, a mean value computing section 72, and a limiter 73.

In the same manner as the output OTW_F of the conventional tracking varactor controlling section 87, the signal generating section 71 generates a digital signal SD having a mean value corresponding to the TUNE_F. The mean value computing section 72 receives a lock detection signal and the SD signal, computes a mean value of the SD over a predetermined period after lock detection, that is, after a PLL has locked; and outputs the result of the computation as an OTWave to the limiter 73. The limiter 73 receives the SD and the OTWave, imposes predetermined limitation on the SD based on the value of the OTWave, and outputs the limited SD as the OTW_F.

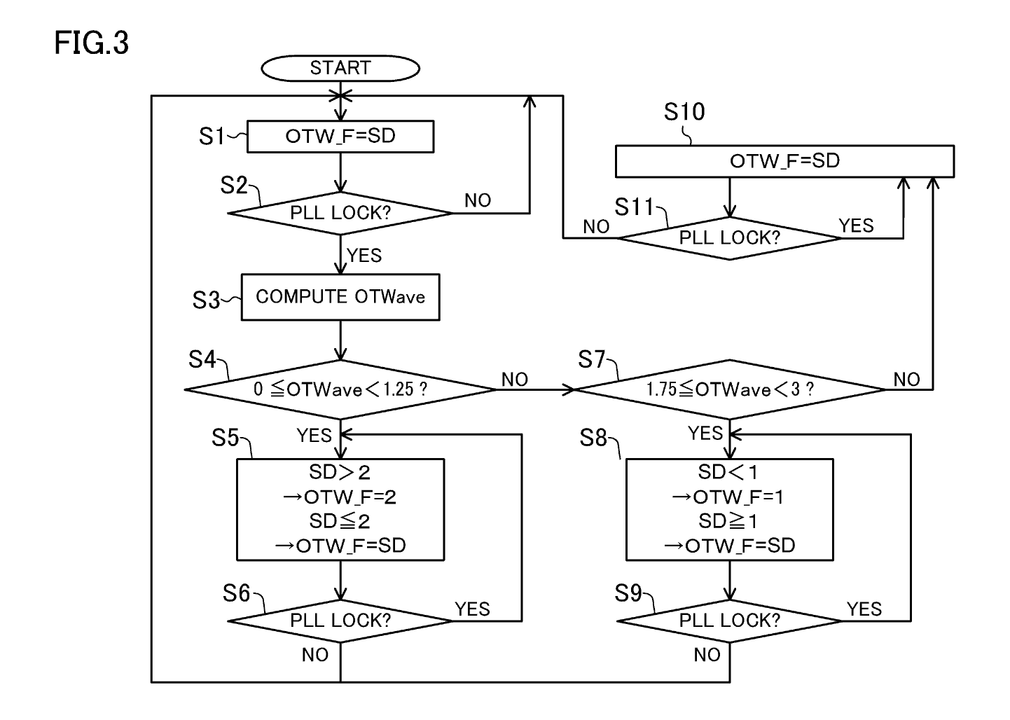

FIG. 3 is a flow chart illustrating a control process performed by the OTF 7 having the limiting function. As illustrated in FIG. 3, tracking operation of the ADPLL frequency synthesizer 101 is first started, and the SD is output without being processed as the OTW_F (S1, S2) until the oscillation frequency of the DCO 10 falls in a preferable frequency range (the PLL locks). When the oscillation frequency of the DCO 10 falls in the preferable frequency range (the PLL locks), the mean value OTWave of the SD over a predetermined period (e.g., 32 cycles of CKVDs) from the lock point is computed (S3). Then, it is determined whether the OTWave is within a predetermined range 1 (e.g., 0 or greater and less than 1.25) or within a predetermined range 2 (e.g., 1.75 or greater and less than 3) (S4, S7). In the case of the OTWave within the predetermined range 1, the upper limit of the OTW_F is set to, for example, 2, wherein when the SD is greater than 2, the OTW_F=2, whereas when the SD is 2 or less, the value of the SD is output without being processed as the OTW_F (S5). In the case of the OTWave within the predetermined range 2, the lower limit of the OTW_F is set to, for example, 1, wherein when the SD is less than 1, the OTW_F=1, whereas when the SD is 1 or greater, the value of the SD is output without being processed as the OTW_F (S8). When the OTWave is neither within the predetermined range 1 nor within the predetermined range 2, it is determined that the SD is far from an integer, so that there is no risk of the occurrence of the carry or the borrow which is the problem discussed above, and the value of the SD is output without being processed as the OTW_F (S10). In this way, the OTF 7 computes the mean value of the SD when the PLL locks, and when the mean value is close to an integer, for example, within the range 1 or the range 2, the OTF 7 compulsorily limits the OTW_F so that the carry or the borrow does not occur. Note that the processes in S5, S8, S10 are repeatedly performed while the lock detection signal is indicating a locked state, and when the PLL is released from the locked state, the OTF 7 goes back to the tracking operation, and the SD is output as the OTW_F (S1, S2) until the oscillation frequency of the DCO 10 falls in the predetermined frequency range (the PLL locks).

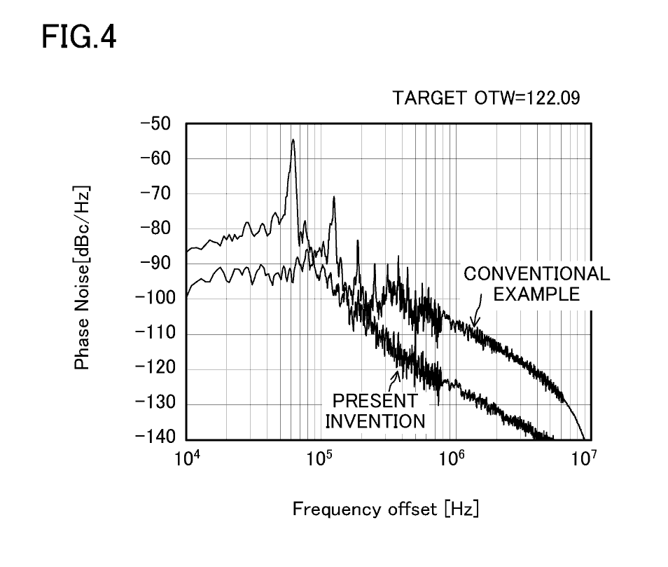

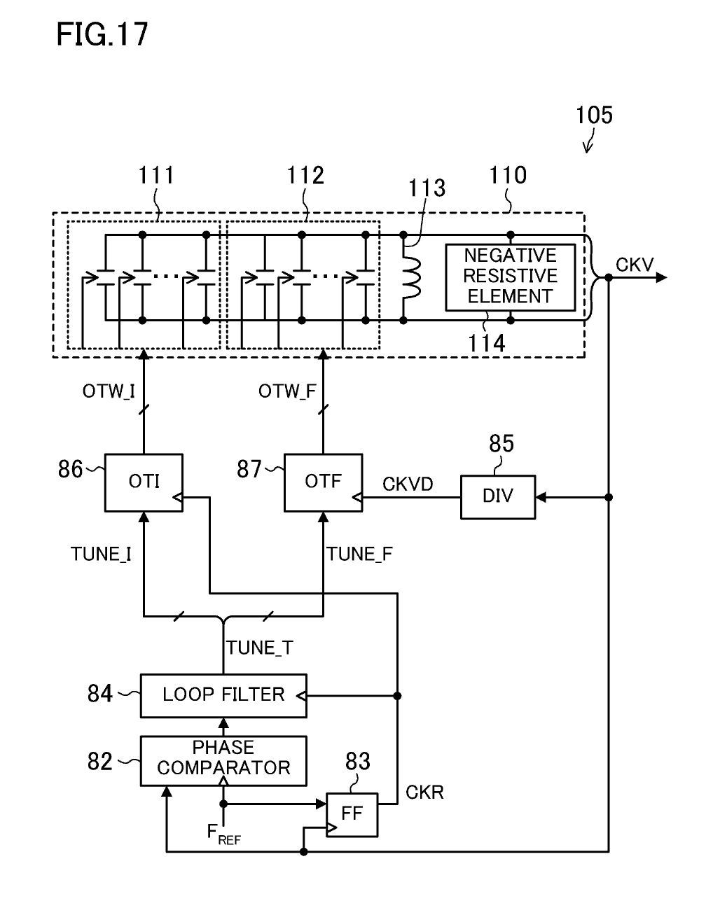

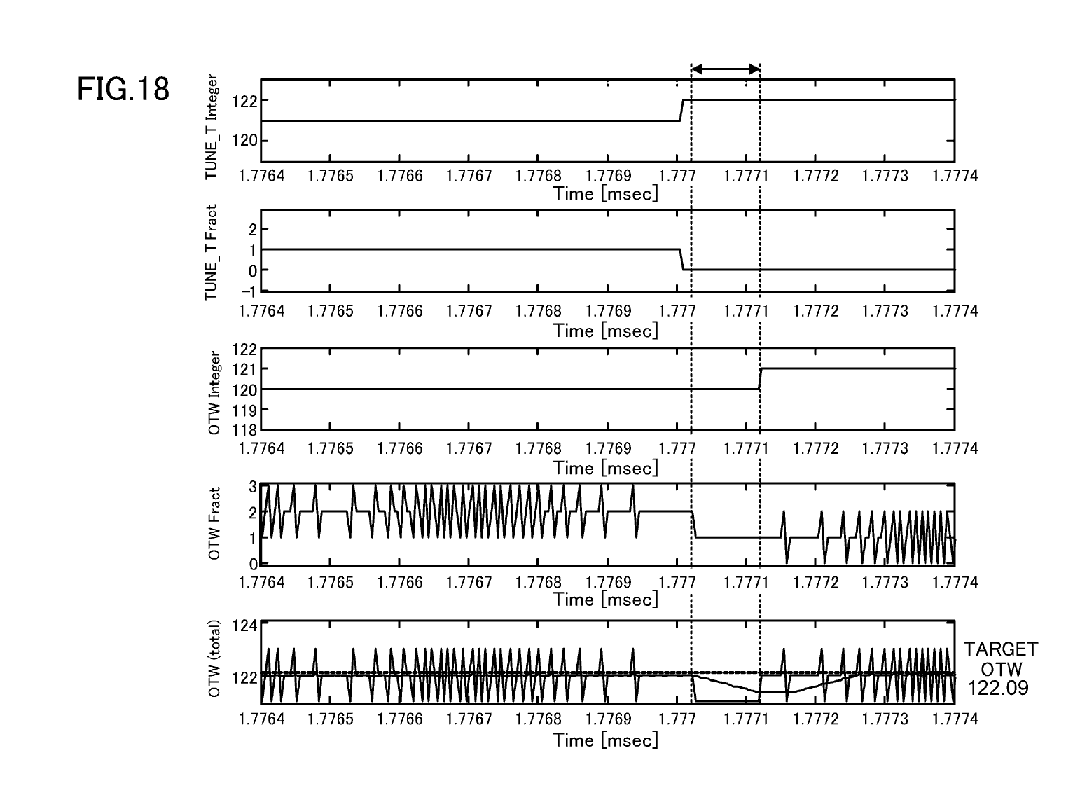

A result of simulation of operation of the ADPLL frequency synthesizer 101 is illustrated in FIG. 4 (“PRESENT INVENTION” of FIG. 4). Note that FIG. 4 also illustrates a result of simulation of the conventional ADPLL frequency synthesizer 105 of FIG. 17 (“CONVENTIONAL EXAMPLE” of FIG. 4) for comparison. As can be seen from the results of FIG. 4, in the ADPLL frequency synthesizer 101 of the present embodiment, even when the target value of the TUNE_T is close to an integer value, the value of the SD tracking the value of the TUNE_F is compulsorily limited after lock detection so that the value of the SD does not track the value of the TUNE_F, thereby obtaining the OTW_F, which is output to control the capacity of the varactor array 12. Thus, an error due to the carry or the borrow is less likely to occur, so that the phase noise characteristics are significantly improved compared to the conventional example.

Although the mean value OTWave of the SD over a predetermined period from the lock point is computed (S3) in the above description, the mean value OTWave over predetermined periods may be computed continuously regardless of lock detection, and limitation may be imposed on the OTW_F immediately after the lock detection by using a result of the computation of the mean value OTWave over a predetermined period directly prior to the lock detection. In the case of relaxed conditions for lock detection, the mean value of the SD may not have sufficiently converged yet even when the lock detection signal indicates the locked state. In such a case, it is preferable to use a result of computation of the mean value of the SD over a predetermined period after a certain time period has elapsed from the lock point, but not over the predetermined period from the lock point.

Although the lock detection signal is externally input to the OTF 7 to determine the locked state in the above description, the determination of the locked state (S2, S6, S9, S11 of FIG. 3) may be made in the OTF 7. To determine the locked state of the PLL in the OTF 7, for example, the mean value of the SD (or the OTW_I+the mean value of the SD) over a predetermined period may be computed a plurality of times at a predetermined cycle, and it may be determined that the PLL is in the locked state if the difference between a plurality of computed values is within a predetermined range.

Although the mean value of the SD over a predetermined period is used as a criterion for imposing limitation on the OTW_F in the above description, it is also possible to use, as the criterion, any characteristics of variation patterns of the SD, such as a maximum value or a minimum value of the SD over a predetermined period, or the number of maximum values (or minimum values) of values which the SD over a predetermined period can have. For example, when values which the SD can have are 0, 1, 2, 3, it is determined that the variation in SD is stable between 0 and 2 if 3 is not included in the values of the SD over a predetermined period even once, and the operation in S5 of FIG. 2 in which the upper limit of the OTW_F is 2 may be performed, and when 0 is not included in the values of the SD over a predetermined period even once, it is determined that the variation in SD is stable between 1 and 3, and the operation in S8 of FIG. 3 in which the lower limit of the OTW_F is 1 may be performed.

In the above description, the values which the SD can have are 0, 1, 2, 3, and the output limiting range of the OTW_F in the locked state of the PLL is limited to two ranges, i.e., the range from 0 to 2, and the range from 1 to 3. However, the values which the SD can have vary depending on the order of a ΔΣ modulator provided in the OTF 7, so that the output limiting range of the OTW_F may be changed based on the order of the ΔΣ modulator.

Moreover, the OTF 7 may include a latch section in an input stage of the signal generating section 71 instead of the limiter 73 and the mean value computing section 72 of FIG. 2. Here, until a certain time period has elapsed since the ADPLL frequency synthesizer 101 locked, the TUNE_F may be input to the signal generating section 71 without being processed, when the certain time period has elapsed since the ADPLL frequency synthesizer 101 locked, the value of the TUNE_F may be latched, and while the locked state continues after the certain time period has elapsed since the ADPLL frequency synthesizer 101 locked, the OTW_F averagely corresponding to the latched TUNE_F may be output.

### Second Embodiment

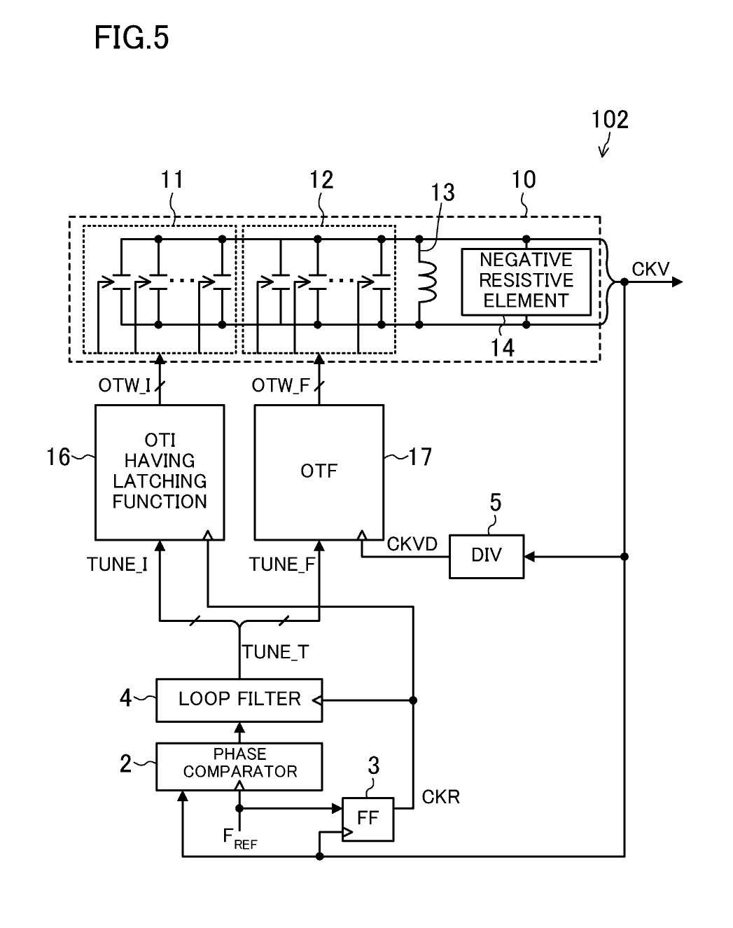

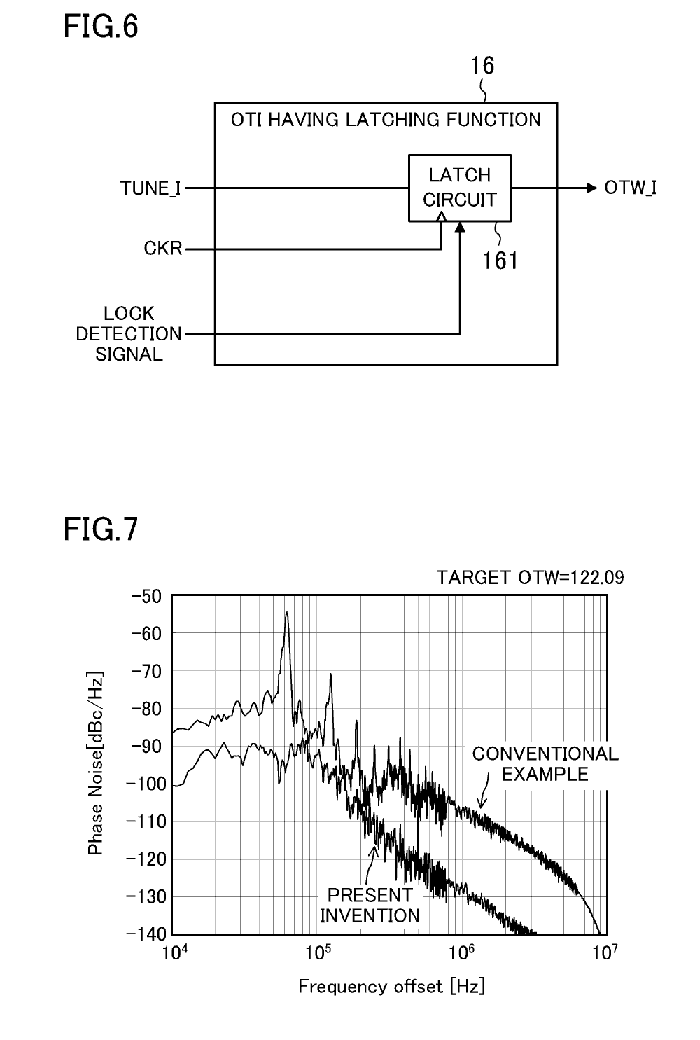

FIG. 5 is a block diagram schematically illustrating a configuration of an ADPLL frequency synthesizer of a second embodiment of the present invention. FIG. 6 is a block diagram illustrating an example configuration of an OTI having a latching function. In FIG. 6, an OTI 16 includes a latch circuit 161.

The latch circuit 161 receives a lock detection signal and a TUNE_I, latches the value of the TUNE_I immediately after lock detection, and outputs the latched value as an OTW_I. Note that a TUNE_F is always used to generate OTW_F without being processed as well as the conventional example. Moreover, until the lock detection, the TUNE_I is also output as the OTW_I without being processed.

A result of simulation of operation of such an ADPLL frequency synthesizer 102 is illustrated in FIG. 7 (“PRESENT INVENTION” of FIG. 7). Note that FIG. 7 also illustrates a result of simulation of the conventional ADPLL frequency synthesizer 105 of FIG. 17 (“CONVENTIONAL EXAMPLE” of FIG. 7) for comparison. As can be seen from the results of FIG. 7, in the ADPLL frequency synthesizer 102 of the present embodiment, even when a target value of the TUNE_I is close to an integer value, the OTW_I whose value tracking the value of the TUNE_I is compulsorily limited after lock detection so that the value of the OTW_I does not track the value of the TUNE_I is output to control the capacity of the varactor array 11. Thus, an error due to the carry or the borrow is less likely to be caused, so that the phase noise characteristics are significantly improved compared to the conventional example.

Although the value of the TUNE_I immediately after the lock point is latched in the above description, the value of the TUNE_I at a point after a certain time period has elapsed from a point immediately after the lock detection may be latched. In the case of relaxed conditions for the lock detection, the value of the TUNE_I may not have sufficiently converged yet even when the lock detection signal indicates the locked state. In such a case, the value of the TUNE_I over a predetermined period after a certain time period has elapsed from the lock point, but not over the predetermined period from the lock point, is preferably used as the value of the OTW_I. The OTI 16 may generate a digital control signal corresponding to the TUNE_I, may latch digital control signal immediately after the lock detection, and may output the digital control signal latched in the locked state as the OTW_I.

(Variations)

In the first embodiment of the present invention, the risk of the occurrence of the carry or the borrow is determined by using characteristics (e.g., mean value or the number of maximum values) of variation patterns of the SD over a predetermined period in a locked state of the ADPLL, and when it is determined that the degree of the risk is high, a decimal part, that is, SD is limited. However, as illustrated in FIG. 6, an integer part, that is, the OTW_I may be limited as in the second embodiment of the present invention. For example, when values which the SD can have are 0, 1, 2, 3, the variation in SD is stable between 0 and 2 if 3 is not included in values of the SD of a predetermined period even once, and even when the carry or the borrow of the TUNE_I occurs, the value of the TUNE_I immediately after the lock point may be used as the OTW_I without tracking the value of the TUNE_I.

### Third Embodiment

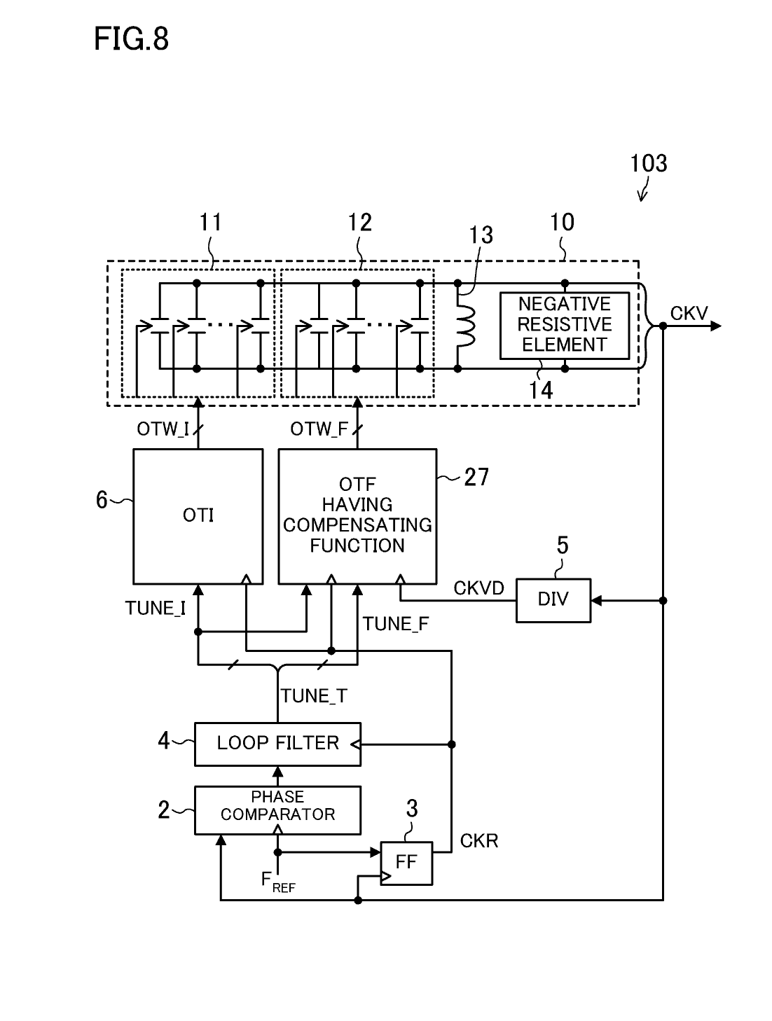

FIG. 8 is a block diagram schematically illustrating a configuration of an ADPLL frequency synthesizer of a third embodiment of the present invention. Elements and configurations in FIG. 8 are the same as those of the first embodiment except that the OTF 7 having the limiting function of the first embodiment is replaced with an OTF 27 having a compensating function in an ADPLL synthesizer 103. The elements and configurations in FIG. 8 which are the same as those of the first embodiment will not repeatedly be described.

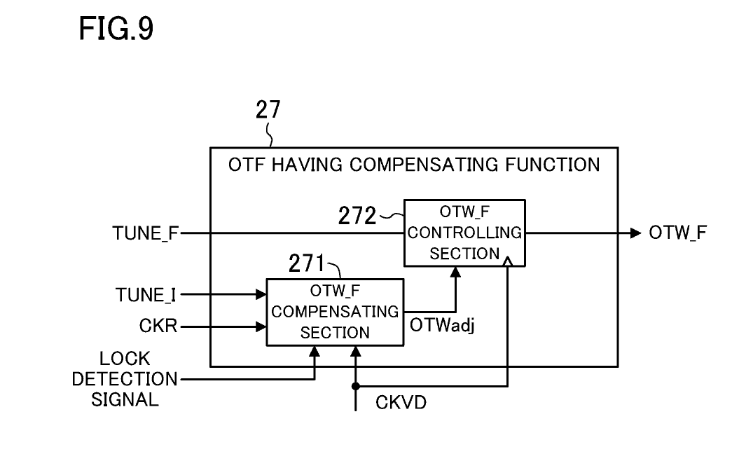

FIG. 9 is a block diagram illustrating an example configuration of the OTF 27 having the compensating function. In FIG. 9, the OTF 27 having the compensating function includes an OTW_F compensating section 271, and an OTW_F controlling section 272.

The OTW_F compensating section 271 receives a lock detection signal, a CKR signal serving as a clock to generate a TUNE_I, a TUNE_T, and a CKVD signal serving as a clock to generate an OTW_F. The value of the TUNE_I after lock detection is read at an internal clock CLK which has a CKR cycle, and is obtained by retiming the CKR by using the CKVD, and a difference ΔTUNE_T Integer between a TUNE_I read last time and a TUNE_I read this time is computed. Outputting an OTW correction value OTWadj corresponding to the value of the ΔTUNE_T Integer to the OTW_F controlling section 272 is started by using the clock CKVD at timing of a start of outputting an OTW_F along with a change of the TUNE_T, and is ended by using the clock CKR at timing of a start of outputting an OTW_I along with the change of the TUNE_T (that is, the OTWadj value is set to 0).

The OTW_F controlling section 272 includes, for example, a simple adder, and outputs, as the OTW_F, a value obtained by adding the OTWadj to a signal SD generated therein.

Note that the value of the OTW correction value OTWadj corresponding to the value of the ΔTUNE_T Integer may be set to +n when the value of the TUNE_I read this time is increased by n compared to that of the TUNE_I read last time, and may be set to −n when the value of the TUNE_I read this time is reduced by n compared to that of the TUNE_I read last time.

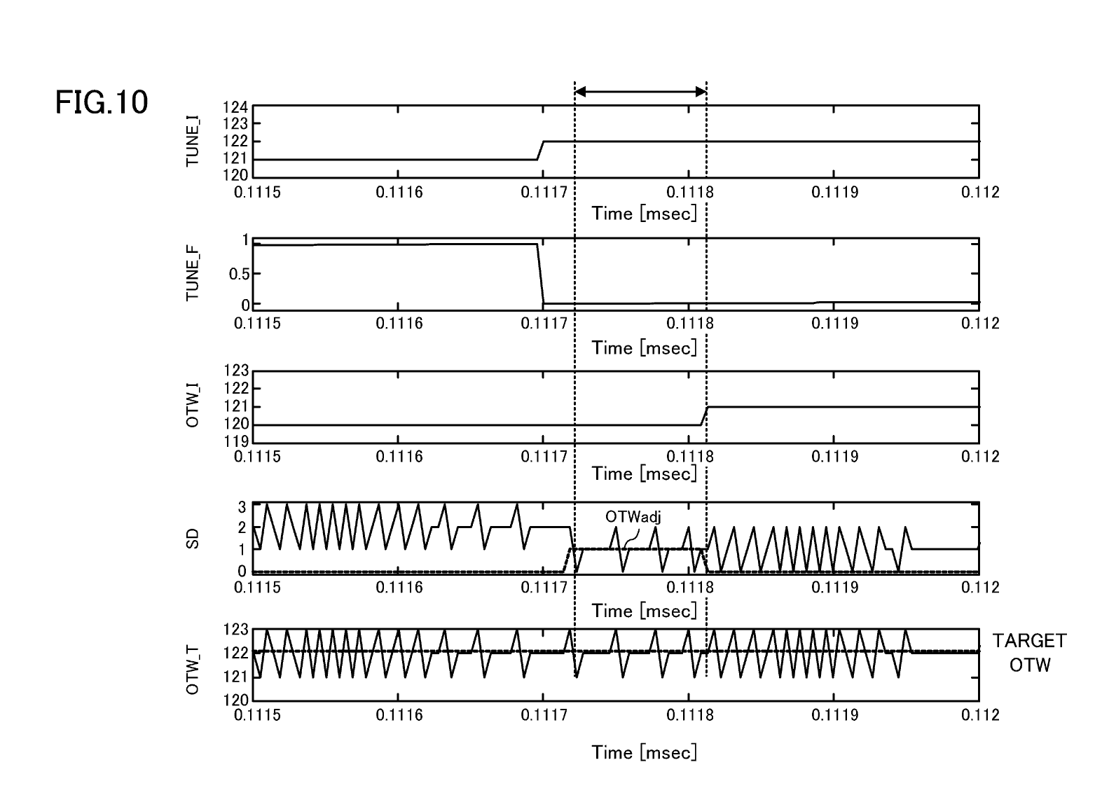

FIG. 10 illustrates a result of simulation of changes of the DCO control signal TUNE_T and a capacity control signal OTW of the third embodiment of the present invention. Conventionally, as the problem discussed above, the OTW_I and the OTW_F are generated from the different clock signals CKR and CKVD, and thus changes of the OTW_I and the OTW_F along with the change of the TUNE_T are offset in timing from each other due to the carry/borrow of the TUNE_T. Therefore, although a capacity control signal OTW(Total) (hereinafter referred to as OTW_T) has converged to the vicinity of an OTW target value (dotted line in the fifth diagram of the figure), an error from the target value temporarily becomes large.

By contrast, in the ADPLL of the present embodiment, as described above, outputting, from the OTW_F compensating section 271, the OTW correction value OTWadj (dotted line in the fourth diagram of the figure) corresponding to the value (=1) of the ΔTUNE_T Integer is started at timing of a start of outputting the SD along with the change of the TUNE_T (OTWadj value=1), and is ended at the timing of the start of outputting the OTW_I along with the change of the TUNE_I (OTWadj value=0). The OTW_T is the total of values of the OTW_I, the SD, and the OTWadj. Thus, an error due to the carry/borrow of the TUNE_T does not temporarily become large.

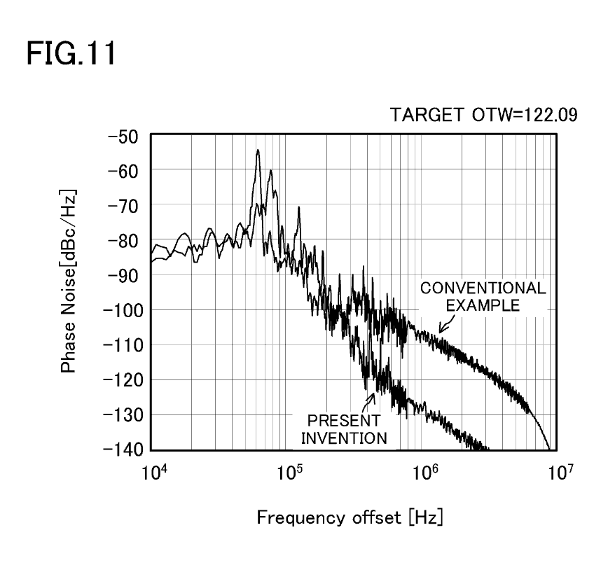

A result of simulation of operation of the ADPLL frequency synthesizer 103 is illustrated in FIG. 11 (“PRESENT INVENTION” of FIG. 11). Note that FIG. 11 also illustrates a result of simulation of the conventional ADPLL frequency synthesizer 105 of FIGS. 4 and 7 (“CONVENTIONAL EXAMPLE” of FIG. 11) for comparison. As can be seen from the results of FIG. 11, in the ADPLL frequency synthesizer 103 of the present embodiment, the error in OTW_T does not temporarily become large even in the case of the carry/borrow of the TUNE_T, and thus the phase noise characteristics are significantly improved compared to the conventional example.

Note that in the above description of the third embodiment, the OTW correction value OTWadj is computed based on the value of the ΔTUNE_T Integer, but the method for computing the OTW correction value OTWadj is not limited to this embodiment. For example, the OTW correction value OTWadj may be computed based on the difference ΔTUNE_T Fract between a TUNE_F read last time and a TUNE_F read this time. In this case, the OTWadj may be −n when the value of the TUNE_F read this time is increased by n compared to the value of the TUNE_F read last time, whereas the OTWadj may be +n when the value of the TUNE_F read this time is reduced by n compared to the value of the TUNE_F read last time.

Although computation and addition of the OTWadj are performed after the lock detection in the third embodiment, the computation and addition may be performed at all times regardless of the lock detection. Also in this case, the phase noise characteristics are improved compared to the conventional example.

Although all the embodiments above describe that the lock detection signal is externally input to the OTI and OTF to determine a locked state when the OTW compensation is performed after the lock detection, but the determination of the locked state (S2, S6, S9, S11, etc. of FIG. 3) may be made in the OTI and the OTF.

As a method for determining the locked state of the PLL in the OTI and the OTF, various methods are possible. For example, a method may be used in which the mean value of the SD (or the mean value of OTW_I+SD) over a predetermined period is computed several times at a predetermined cycle, and it is determined that the PLL is in the locked state when the difference between a plurality of computed values is within a predetermined range. Alternatively, a method may be used in which the process of detecting a change of the OTW_I of a predetermined period is performed, and when the change is not found, it is determined that the PLL is in the locked state.

### Fourth Embodiment

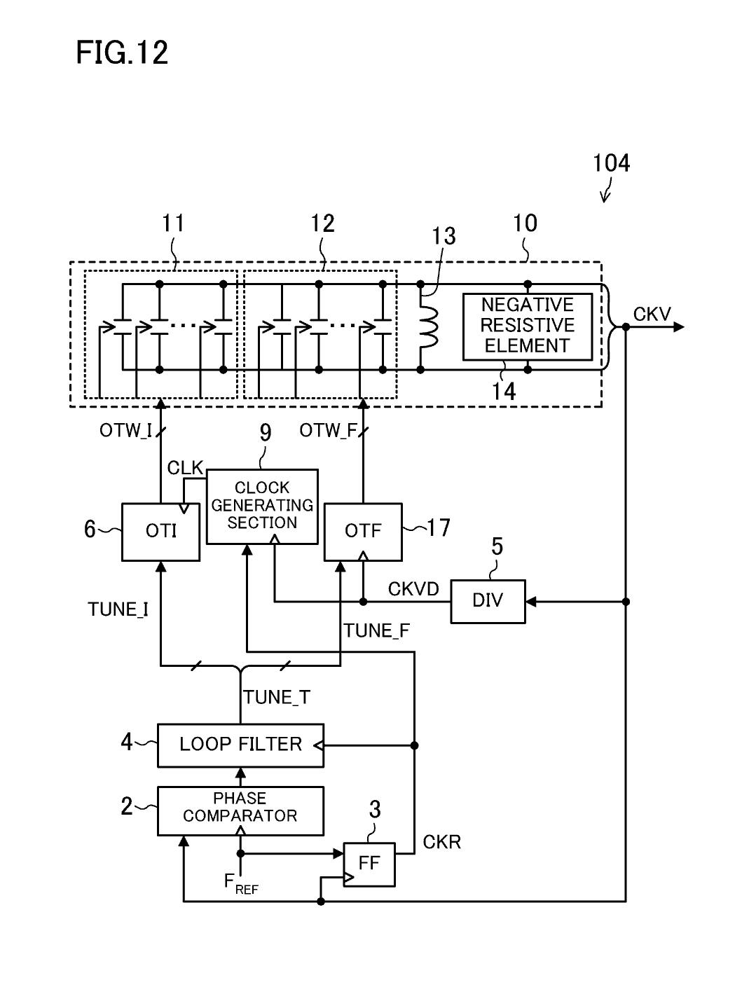

FIG. 12 is a block diagram illustrating a configuration of an ADPLL frequency synthesizer of a fourth embodiment of the present invention. In an ADPLL frequency synthesizer 104 of FIG. 12, the OTF 7 in the ADPLL frequency synthesizer 101 of FIG. 1 described as the first embodiment is replaced with the OTF 17 in the ADPLL frequency synthesizer 102 of FIG. 5 described as the second embodiment, and a drive clock of an OTI 6 is changed from CKR to CLK. Other components and configurations are the same as those of the first embodiment, and the description thereof is not repeated.

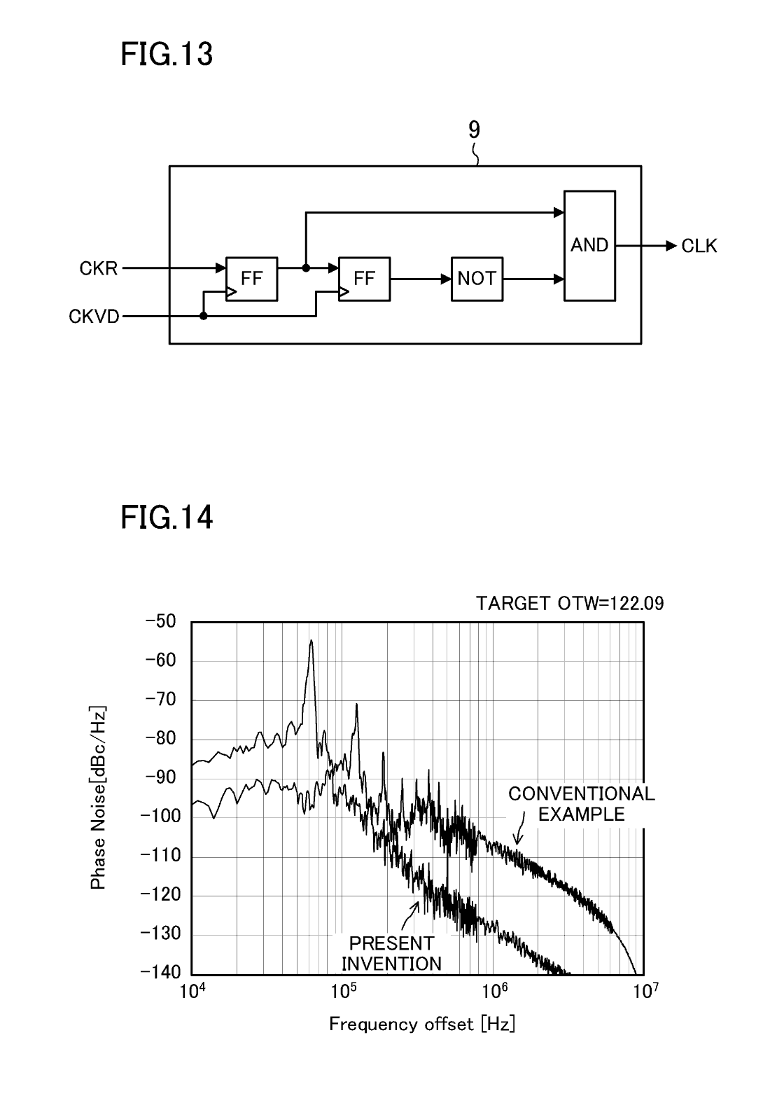

FIG. 13 is a block diagram illustrating an example configuration of a clock generating section 9. In FIG. 13, the clock generating section 9 includes a flip-flop circuit (FF), an inverter circuit (NOT), and an AND circuit (AND), and generates the clock CLK obtained by retiming the clock CKR used to generate a TUNE_T by a drive clock CKVD of the OTF 17.

In this way, driving the OTI 6 at the clock CLK obtained by retiming by the drive clock CKVD of the OTF 17 can shorten an offset time of timing of changes of outputs of the OTI 6 and the OTF 17 with respect to the change of the TUNE_T compared to the conventional example.

A result of simulation of operation of the ADPLL frequency synthesizer 104 is illustrated in FIG. 14 (“PRESENT INVENTION” of FIG. 14). Note that FIG. 14 also illustrates a result of simulation of the conventional ADPLL frequency synthesizer 105 of FIGS. 4, 7 (“CONVENTIONAL EXAMPLE” of FIG. 14) for comparison. As can be seen from the results of FIG. 14, in the ADPLL frequency synthesizer 104 of the present embodiment, the error of the OTW_T is less likely to be temporarily enlarged even in the case of the carry/borrow of the TUNE_T, so that the phase noise characteristics are significantly improved compared to the conventional example.

### Application Examples

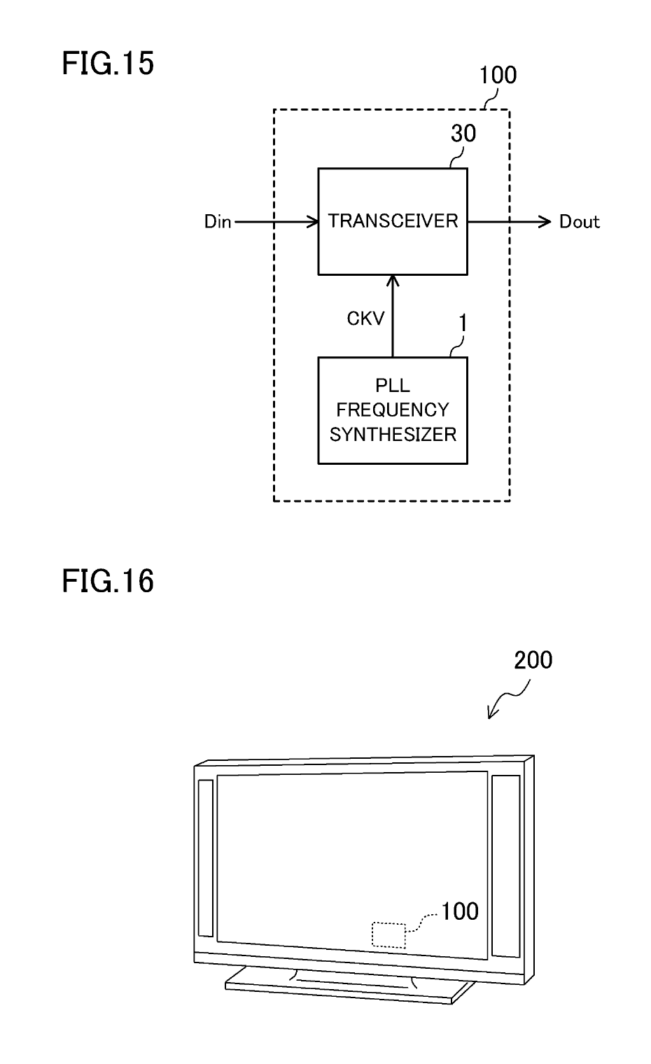

FIG. 15 is a view illustrating a configuration of a wireless communication device 100 of an application example. The wireless communication device 100 includes an ADPLL frequency synthesizer 1, and a transceiver 30 configured to receive a data signal Din in synchronization with a CKV, to process the Din, and to transmit the processed data as a data signal Dout to the outside. Note that the ADPLL frequency synthesizer 1 is the ADPLL frequency synthesizer of any one of the first to fourth embodiments. The wireless communication device 100 can be used as a tuner 100 installed in, for example, a television set 200 illustrated in FIG. 16.

What is claimed is:

1. A PLL frequency synthesizer comprising:
a phase comparator configured to detect a phase difference between a reference clock signal and an output signal of the PLL frequency synthesizer;
a loop filter configured to output a control value composed of a total of an integer value and a decimal value which are based on the phase difference;
a first frequency controlling section configured to output a first digital control signal corresponding to the integer value in synchronization with a first clock signal;
a second frequency controlling section configured to output a second digital control signal representing the decimal value as a mean value in synchronization with a second clock signal which is higher in frequency than the first clock signal, where when the PLL frequency synthesizer is in a locked state, the second frequency controlling section limits a range of values which the second digital control signal can have to a range in the locked state; and
a digital controlled oscillator configured to oscillate at a frequency based on a combination of frequency control by the first digital control signal and frequency control by the second digital control signal.

2. The PLL frequency synthesizer of claim 1, wherein
the second frequency controlling section includes:
a signal generating section configured to generate a third digital control signal representing the decimal value as a mean value;
a mean value computing section configured to compute a mean value of the third digital control signal over a certain period when the PLL frequency synthesizer is in a locked state; and
a limiter configured to output, as the second digital control signal, a digital signal obtained by limiting an upper limit or a lower limit of the third digital control signal based on the computed mean value.

3. The PLL frequency synthesizer of claim 1, wherein
the second frequency controlling section latches the decimal value of when the PLL frequency synthesizer is in a locked state, and outputs, as the second digital control signal, a digital control signal representing the latched decimal value as a mean value.

4. A wireless communication device comprising:
the PLL frequency synthesizer of claim 1; and
a transceiver configured to transmit or receive data by using a signal output from the PLL frequency synthesizer.

5. A PLL frequency synthesizer comprising:
a phase comparator configured to detect a phase difference between a reference clock signal and an output signal of the PLL frequency synthesizer;
a loop filter configured to output a control value composed of a total of an integer value and a decimal value which are based on the phase difference;
a first frequency controlling section configured to output a first digital control signal corresponding to the integer value in synchronization with a first clock signal, where when the PLL frequency synthesizer is in a locked state, the first frequency controlling section constantly outputs the first digital control signal in the locked state;
a second frequency controlling section configured to output a second digital control signal representing the decimal value as a mean value in synchronization with a second clock signal which is higher in frequency than the first clock signal; and
a digital controlled oscillator configured to oscillate at a frequency based on a combination of frequency control by the first digital control signal and frequency control by the second digital control signal.

6. The PLL frequency synthesizer of claim 5, wherein
the first frequency controlling section latches a digital control signal corresponding to the integer value of when the PLL frequency synthesizer enters a locked state, and outputs the latched digital control signal as the first digital control signal.

7. The PLL frequency synthesizer of claim 5, wherein
the first frequency controlling section latches the integer value of when the PLL frequency synthesizer enters a locked state, and outputs, as the first digital control signal, a digital control signal corresponding to the latched integer value.

8. A wireless communication device comprising:
the PLL frequency synthesizer of claim 5; and
a transceiver configured to transmit or receive data by using a signal output from the PLL frequency synthesizer.

9. A PLL frequency synthesizer comprising:
a phase comparator configured to detect a phase difference between a reference clock signal and an output signal of the PLL frequency synthesizer;
a loop filter configured to output a control value composed of a total of an integer value and a decimal value which are based on the phase difference;
a first frequency controlling section configured to output a first digital control signal corresponding to the integer value in synchronization with a first clock signal;
a second frequency controlling section configured to output a second digital control signal representing the decimal value as a mean value in synchronization with a second clock signal which is higher in frequency than the first clock signal, where when the PLL frequency synthesizer is in a locked state, the second frequency controlling section compensates an amount of change of the integer value in a period after the integer value has changed before the first digital control signal changes; and
a digital controlled oscillator configured to oscillate at a frequency based on a combination of frequency control by the first digital control signal and frequency control by the second digital control signal.

10. A wireless communication device comprising:
the PLL frequency synthesizer of claim 9; and
a transceiver configured to transmit or receive data by using a signal output from the PLL frequency synthesizer.

11. A PLL frequency synthesizer comprising:
a phase comparator configured to detect a phase difference between a reference clock signal and an output signal of the PLL frequency synthesizer;
a loop filter configured to output a control value composed of a total of an integer value and a decimal value which are based on the phase difference;
a first frequency controlling section configured to output a first digital control signal corresponding to the integer value in synchronization with a first clock signal;
a second frequency controlling section configured to output a second digital control signal representing the decimal value as a mean value in synchronization with a second clock signal which is higher in frequency than the first clock signal;
a clock generating section configured to retime the reference clock signal by the output of the PLL frequency synthesizer to obtain a retiming clock, and to further retime the retiming clock by the second clock signal to generate a clock signal as the first clock signal; and
a digital controlled oscillator configured to oscillate at a frequency based on a combination of frequency control by the first digital control signal and frequency control by the second digital control signal.

12. A wireless communication device comprising:
the PLL frequency synthesizer of claim 11, and
a transceiver configured to transmit or receive data by using a signal output from the PLL frequency synthesizer.
